(19) United States
(12) Patent Application Publication
(10) Pub. No.: US 2013/0008687 A1
(43) Pub. Date: Jan. 10, 2013

(54) CONDUCTIVE FILM STRUCTURE CAPABLE OF RESISTING MOISTURE AND OXYGEN AND ELECTRONIC APPARATUS USING THE SAME

(75) Inventors: Mike Lu, New Taipei City (TW); Sheng-Feng Chung, Hsinchu City (TW); Bao-Shun Yau, Kaohsiung City (TW); Cheng-Yi Chiang, Kaohsiung City (TW)

(73) Assignee: INDUSTRIAL TECHNOLOGY RESEARCH INSTITUTE, Hsinchu (TW)

(21) Appl. No.: 13/304,385

(22) Filed: Nov. 24, 2011

Related U.S. Application Data
(60) Provisional application No. 61/505,546, filed on Jul. 8, 2011.

(51) Int. Cl. H01B 7/28

(52) U.S. Cl. 174/119 C

(57) ABSTRACT

A conductive film structure capable of resisting moisture and oxygen and an electronic apparatus using the same are provided. The conductive film structure includes a metal electrode, a metal oxide layer, and an insulating layer. The metal oxide layer is disposed on the metal electrode and includes an oxide of the metal electrode. The insulating layer covers the metal oxide layer and has at least one pinhole therein.

### CROSS-REFERENCE TO RELATED APPLICATION

This application claims the priority benefits of U.S. provisional application Ser. No. 61/505,546, filed on Jul. 8, 2011. The entirety of the above-mentioned patent applications is hereby incorporated by reference herein and made a part of this specification.

### BACKGROUND

1. Technical Field

The disclosure relates to a conductive film structure capable of resisting moisture and oxygen and an electronic apparatus using the same.

2. Related Art

Comparing to conventional rigid substrates, flexible substrates have a wide application scope and are flexible, portable, safe, and broadly applied. However, flexible substrates have poor water and oxygen resistance, poor chemical resistance, and large thermal expansion coefficients. Since the typical flexible substrate fails to resist the permeation of moisture and oxygen completely, the electronic device on the substrate is rapidly deteriorated so that the device fabricated has short lifespan and can not satisfy market demands.

According to the current development of flexible electronic apparatuses, the application of polyethylene terephthalate (PET) or other optical plastic material as the substrate of the flexible device has become an inevitable trend in the future. However, plastic substrates have poor water and oxygen resisting ability and thus suffer from moisture and oxygen permeation, which then leads to the deterioration of materials in the electronic device and results in the degradation of the device or the reduction in its lifespan.

Therefore, in order to maintain the high performance and stability of the electronic device, a conductive film with high moisture and oxygen resistance has to be developed to prevent moisture and oxygen from permeating into the electronic device and damaging the active layer in the electronic device.

### SUMMARY

A conductive film structure capable of resisting moisture and oxygen is introduced herein. The conductive film structure includes a metal electrode, a metal oxide layer, and an insulating layer. The metal oxide layer is disposed on the metal electrode, where a material of the metal oxide layer is an oxide of the metal electrode. The insulating layer covers the metal oxide layer.

A conductive film structure capable of resisting moisture and oxygen is introduced herein. The conductive film structure includes a transparent conductive layer, a transparent metal electrode, a transparent metal oxide layer, and an insulating layer. The transparent metal electrode is disposed on the transparent conductive layer. The transparent metal oxide layer is disposed on the transparent metal electrode, where a material of the transparent metal oxide layer is an oxide of the transparent metal electrode. The insulating layer covers the transparent metal oxide layer.

An electronic apparatus having the conductive film structure capable of resisting moisture and oxygen is introduced herein.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic cross-sectional diagram illustrating a conductive film structure capable of resisting moisture and oxygen according to an exemplary embodiment.

FIG. 2 is a schematic top view of the conductive film structure capable of resisting moisture and oxygen shown in FIG. 1.

FIG. 3 is a schematic cross-sectional diagram illustrating an oxidation/diffusion in the conductive film structure capable of resisting moisture and oxygen shown in FIG. 1.

FIG. 4 is a schematic top view of the conductive film structure capable of resisting moisture and oxygen shown in FIG. 3.

FIG. 5 is a schematic cross-sectional diagram illustrating a conductive film structure capable of resisting moisture and oxygen according to an exemplary embodiment.

FIG. 6 is a schematic top view of the conductive film structure capable of resisting moisture and oxygen shown in FIG. 5.

FIG. 7 is a schematic cross-sectional diagram illustrating an oxidation/diffusion in the conductive film structure capable of resisting moisture and oxygen shown in FIG. 5.

FIG. 8 is a schematic top view of the conductive film structure capable of resisting moisture and oxygen shown in FIG. 7.

### DETAILED DESCRIPTION OF DISCLOSED EMBODIMENTS

### First Exemplary Embodiment

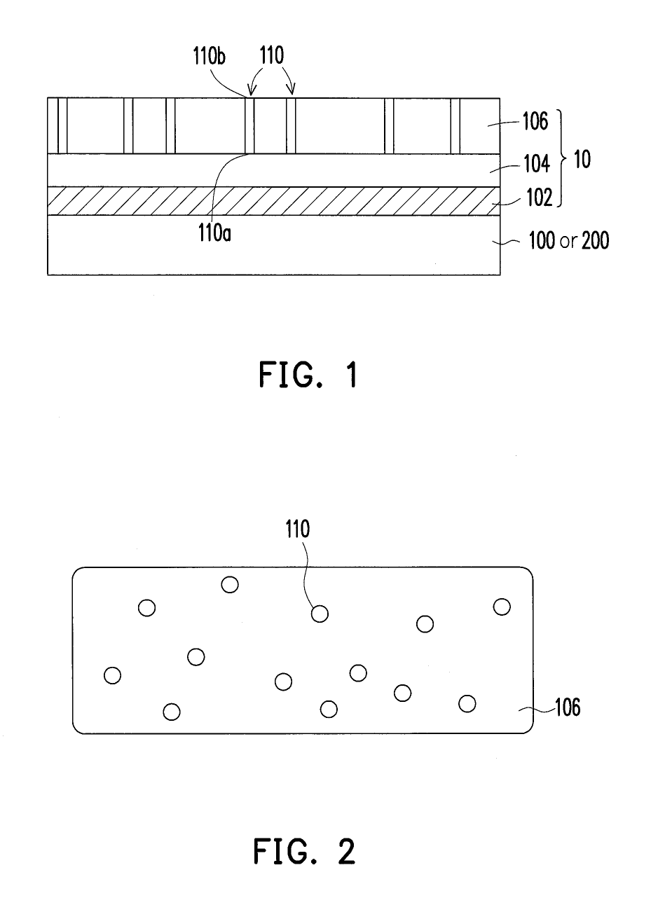

FIG. 1 is a schematic cross-sectional diagram illustrating a conductive film structure capable of resisting moisture and oxygen according to an exemplary embodiment. FIG. 2 is a schematic top view of the conductive film structure capable of resisting moisture and oxygen shown in FIG. 1. Referring to FIGS. 1 and 2 simultaneously, a conductive film structure 10 capable of resisting moisture and oxygen in the exemplary embodiment includes a metal electrode 102, a metal oxide layer 104, and an insulating layer 106.

The metal electrode 102 includes a metal or a composite metal. In other words, the metal electrode 102 is fabricated using a single metal material or formed by composing a plurality of metals. According to the exemplary embodiment, the single metal material is, for example, aluminum (Al), copper (Cu), silver (Ag), platinum (Pt), gold (Au), or other metals. The composite metal includes silver/copper (Ag/Cu), aluminum/silver (Al/Ag), aluminum/platinum (Al/Pt), gold/copper (Au/Cu), platinum/gold (Pt/Au), zinc/copper (Zn/Cu), or other composite metals. Here, the composite metal refers to an alloy formed by two or more metals. For instance, the composite metal Ag/Cu is an alloy composed by Ag and Cu. In addition, a method of forming the metal electrode 102 includes a physical vapor deposition, a chemical vapor deposition, a sputtering process, a printing process, a shadow mask deposition, or an entire deposition.

The metal oxide layer 104 is disposed on the metal electrode 102. Especially, a material of the metal oxide layer 104 is an oxide of the metal electrode 102. Here, a method of forming the metal oxide layer 104 includes the following. For example, after the metal electrode 102 is formed, an oxidation process is performed to the metal electrode 102 to form a metal oxide layer 104 on a surface of the metal electrode 102. The oxidation process is a dry oxidation process or a wet oxidation process. The metal oxide layer 104 formed with the oxidation process aforementioned has a thickness ranging from 1 nanometer (nm) to 5 nm. According to the exemplary embodiment, the metal electrode 102 and the metal oxide layer 104 can be formed in the same reaction chamber. Consequently, the process of forming the metal electrode 102 and the metal oxidation layer 104 can also be referred as an in-situ process.

Since the material used for fabricating the metal oxide layer 104 is an oxide of the metal electrode 102, when the metal electrode 102 is fabricated with a single metal material (i.e. Al, Cu, Ag, Pt, Au, or other metals), the material of the metal oxide layer 104 covering on the surface of the metal electrode 102 includes aluminum oxide, copper oxide, silver oxide, platinum oxide, or gold oxide. The aluminum oxide includes Al₂O₃, the copper oxide includes CuO, the silver oxide includes AgO and/or Ag₂O, the platinum oxide includes PtO₂, and the gold oxide includes Au₂O₃.

Similarly, when the metal electrode 102 is fabricated using a composite metal material, for example, an Ag/Cu alloy, an Al/Ag alloy, an Al/Pt alloy, an Au/Cu alloy, a Pt/Au alloy, or a Zn/Cu alloy, then the material of the metal oxide layer 104 formed on the surface of the metal electrode 102 includes an oxide of the metal or composite metal, for example, silver oxide, copper oxide, or an Ag/Cu alloy oxide; aluminum oxide, silver oxide, or an Al/Ag alloy oxide; aluminum oxide, platinum oxide, or an Al/Pt alloy oxide; gold oxide, copper oxide, or an Au/Cu alloy oxide; platinum oxide, gold oxide, or a Pt/Au alloy oxide; zinc oxide, copper oxide, or a Zn/Cu alloy oxide.

The insulating layer 106 covers the metal oxide layer 104. The insulating layer 106 has at least one pinhole 110 passing through the insulating layer 106 such that one end 110a of the pinhole 110 contacts the metal oxide layer 106. According to the exemplary embodiment, the insulating layer 106 includes silicon oxide, silicon nitride, titanium oxide, ethylene vinyl acetate (EVA), epoxy, polytetrafluoroethylene (PTFE), ethylene-tetrafluoroethylene (ETFE), or a combination thereof. A method of forming the insulating layer 106 includes a physical vapor deposition, a chemical vapor deposition, a sputtering process, a printing process, a shadow mask deposition, or an entire deposition.

According to the exemplary embodiment, when the insulating layer 106 is formed using any one of the above deposition methods, fine pinholes 110 are more or less may present in the insulating layer 106. With the presence of these pinholes 110, moisture and oxygen from the external environment then permeate or diffuse into a film layer under the insulating layer 106 through the pinholes 110. In other words, since one end 110b of each of the pinholes 110 is exposed to the external environment and the other end 110a of each pinhole 110 exposes the film layer under the insulating layer 106, moisture and oxygen from the external environment can then permeate or diffuse into the film layer under the insulating layer 106 through the pinholes 110.

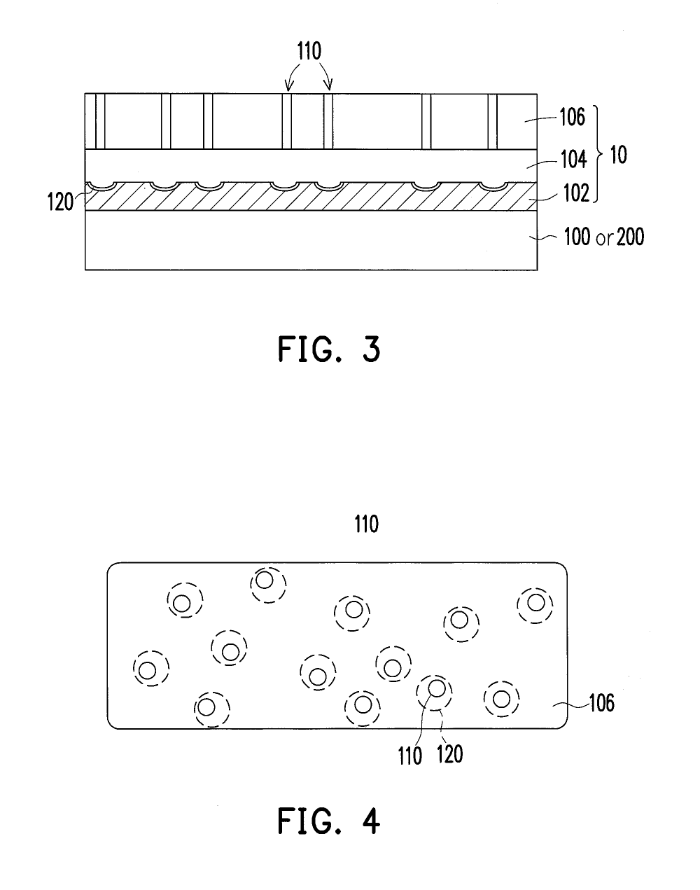

In the exemplary embodiment, since the metal oxide layer 104 is formed above the metal electrode 102, the pinholes 110 passing through the insulating layer 106 expose the metal oxide layer 104. When moisture and oxygen from the external environment pass through the pinholes 110 and permeate or diffuse into the film layer under the insulating layer 106, moisture and oxygen undergo an oxidation/diffusion in the metal oxide layer 104, thereby forming a diffused oxide 120 as shown in FIGS. 3 and 4.

In particular, since the metal oxide layer 104 is an oxide material, when moisture and oxygen diffuse or permeate into the metal oxide layer 104, the oxidation effect generated by moisture and oxygen in the metal oxide layer 104 is limited or slow. In other words, moisture and oxygen are resisted by the metal oxide layer 104 and can not diffuse to the metal electrode. Since the metal electrode 102 located under the metal oxide layer 104 is not oxidized or corroded by moisture and oxygen, the metal electrode 102 can obtain its original electric property.

According to an exemplary embodiment, the conductive film structure 10 can be disposed on a substrate 100 or an electronic device 200.

The substrate 100 can be a rigid substrate (e.g. a glass substrate or a silicon substrate) or a flexible substrate (e.g. a plastic substrate or a metal substrate). When disposed on the substrate 100, the conductive film structure 10 can be adopted as a simple conductive wire structure, electrode structure, or conductive layer structure.

According to another exemplary embodiment, the conductive film structure 10 is disposed on the electronic device 200 to constitute the electronic apparatus. The electronic device 200 includes a display device, a solar cell device, a light emitting diode (LED) device, a flexible circuit board device, or a field effect transistor device. In other words, the conductive film structure 10 disposed on the electronic device 200 is applied as a part of the electronic apparatus. For instance, when disposed on the solar cell device, the conductive film structure 10 can be utilized as a contact electrode in the solar cell device. When disposed on the LED device, the conductive film structure 10 can be adopted an electrode layer in the LED device.

### Second Exemplary Embodiment

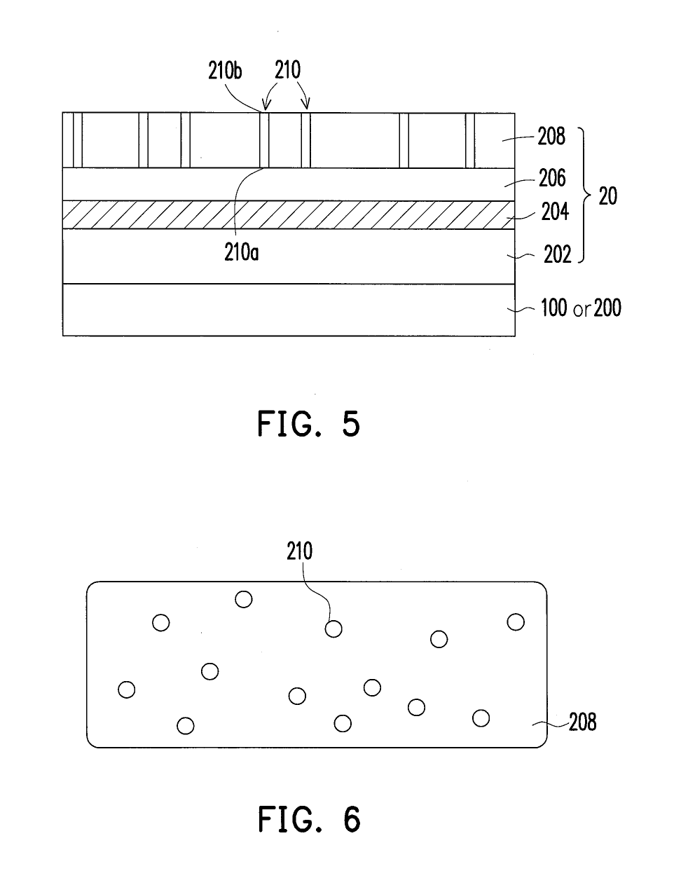

FIG. 5 is a schematic cross-sectional diagram illustrating a conductive film structure capable of resisting moisture and oxygen according to an exemplary embodiment. FIG. 6 is a schematic top view of the conductive film structure capable of resisting moisture and oxygen shown in FIG. 5. Referring to FIGS. 5 and 6 simultaneously, a conductive film structure 20 capable of resisting moisture and oxygen in the exemplary embodiment includes a transparent conductive layer 202, a transparent metal electrode 204, a transparent metal oxide layer 206, and an insulating layer 208.

The transparent conductive layer 202 includes an inorganic conductive material or an organic conductive material. The inorganic conductive material includes indium tin oxide (ITO), fluorine-doped tin oxide (FTO), zinc oxide (ZnO), aluminum-doped zinc oxide (AZO), or indium zinc tin oxide (IZTO). The inorganic conductive material may also be silver nano-wires. The organic conductive material includes conjugated polymer, carbon nanotube, or graphene. In addition, a method of forming the transparent conductive layer 202 includes a physical vapor deposition, a chemical vapor deposition, a sputtering process, a printing process, a shadow mask deposition, or an entire deposition.

The transparent metal electrode 204 is disposed on the transparent conductive layer 202. According to the exemplary embodiment, the transparent metal electrode 204 has a thickness ranging from 5 nm to 10 nm. That is, since the thickness of the metal electrode 204 is thin, the metal electrode 204 can be light transmissive or transparent. Similarly, the transparent metal electrode 204 includes a metal or a composite metal. In other words, the transparent metal electrode 204 is fabricated using a single metal material or formed by composing a plurality of types of metals. According to the exemplary embodiment, the single metal material is, for example, Al, Cu, Ag, Pt, Au, or other metals. The composite metal includes Ag/Cu, Al/Ag, Al/Pt, Au/Cu, Pt/Au, Zn/Cu, or other composite metals. Here, the composite metal refers to an alloy formed by two or more types of metals. For instance, the composite metal Ag/Cu is an alloy composed by Ag and Cu. In addition, a method of forming the transparent metal electrode 204 includes a physical vapor deposition, a chemical vapor deposition, a sputtering process, a printing process, a shadow mask deposition, or an entire deposition.

The transparent metal oxide layer 206 is disposed on the transparent metal electrode 204, where a material of the transparent metal oxide layer 206 is an oxide of the transparent metal electrode 204. Here, a method of forming the transparent metal oxide layer 206 includes the following. For example, after the transparent metal electrode 204 is formed, an oxidation process is performed to the transparent metal electrode 204 to form a metal oxide layer 206 on a surface of the transparent metal electrode 204. The oxidation process is a dry oxidation process or a wet oxidation process. The transparent metal oxide layer 206 formed with the oxidation process aforementioned has a thickness ranging from 1 nm to 5 nm. According to the exemplary embodiment, the transparent metal electrode 204 and the transparent metal oxide layer 206 can be formed in the same reaction chamber. Consequently, the process of forming the transparent metal electrode 204 and the transparent metal oxidation layer 206 can also be referred as an in-situ process.

Since the material used for fabricating the transparent metal oxide layer 206 is an oxide of the transparent metal electrode 204, when the transparent metal electrode 204 is fabricated with a single metal material (i.e. Al, Cu, Ag, Pt, Au, or other metals), the material of the transparent metal oxide layer 206 covering on the surface of the transparent metal electrode 204 includes aluminum oxide, copper oxide, silver oxide, platinum oxide, or gold oxide. The aluminum oxide includes Al₂O₃, the copper oxide includes CuO, the silver oxide includes AgO and/or Ag₂O, the platinum oxide includes PtO₂, and the gold oxide includes Au₂O₃.

Similarly, when the transparent metal electrode 204 is fabricated using a composite metal material, for example, an Ag/Cu alloy, an Al/Ag alloy, an Al/Pt alloy, an Au/Cu alloy, a Pt/Au alloy, or a Zn/Cu alloy, then the material of the transparent metal oxide layer 206 formed on the surface of the transparent metal electrode 204 includes an oxide of metal or the composite metal, for example, silver oxide, copper oxide, or an Ag/Cu alloy oxide; aluminum oxide, silver oxide, or an Al/Ag alloy oxide; aluminum oxide, platinum oxide, or an Al/Pt alloy oxide; gold oxide, copper oxide, or an Au/Cu alloy oxide; platinum oxide, gold oxide, or a Pt/Au alloy oxide; zinc oxide, copper oxide, or a Zn/Cu alloy oxide.

The insulating layer 208 covers the transparent metal oxide layer 206. The insulating layer 208 has at least one pinhole 210 passing through the insulating layer 208 for one end 210a of the pinhole 210 to contact the transparent metal oxide layer 206. According to the exemplary embodiment, the insulating layer 208 includes silicon oxide, silicon nitride, titanium oxide, EVA, epoxy, polytetrafluoroethylene (PTFE), ethylene-tetrafluoroethylene (ETFE), or a combination thereof. Moreover, a method of forming the insulating layer 208 includes a physical vapor deposition, a chemical vapor deposition, a sputtering process, a printing process, a shadow mask deposition, or an entire deposition.

In the exemplary embodiment, when the insulating layer 208 is formed using any one of the above deposition methods, fine pinholes 210 are more or less may present in the insulating layer 208. With the presence of these pinholes 210, moisture and oxygen from the external environment then permeate or diffuse into a film layer under the insulating layer 208 through the pinholes 210. In other words, since one end 210b of each of the pinholes 210 is exposed to the external environment and the other end 210a of each pinhole 210 exposes the film layer under the insulating layer 208, moisture and oxygen from the external environment can then permeate or diffuse into the film layer under the insulating layer 208 through the pinholes 210.

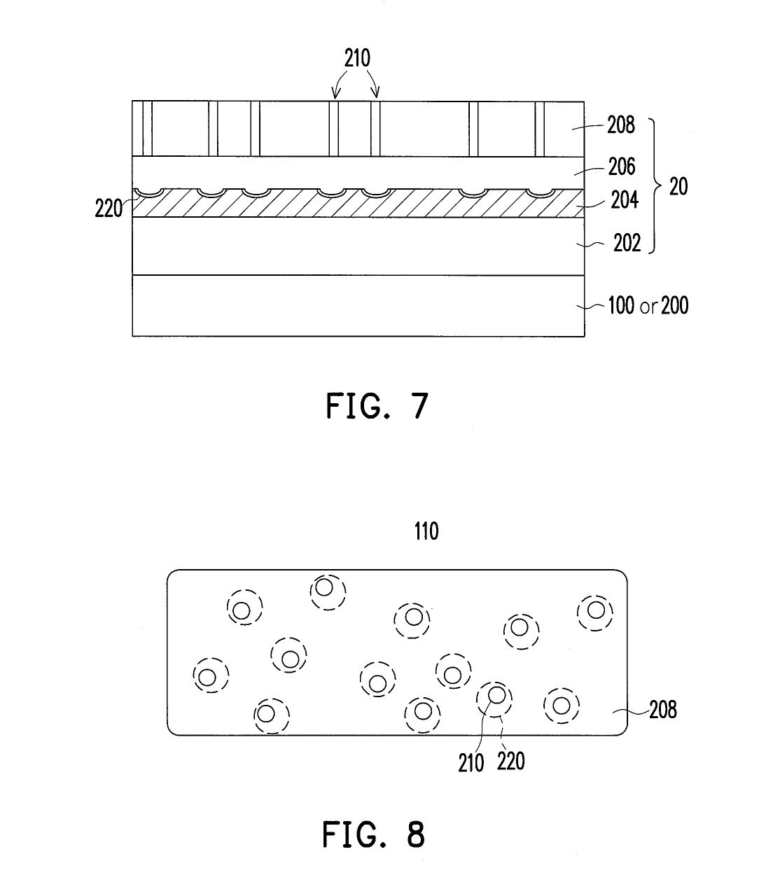

In the exemplary embodiment, since the transparent metal oxide layer 206 is formed above the transparent metal electrode 204, the pinholes 210 passing through the insulating layer 208 expose the transparent metal oxide layer 206 disposed under the insulating layer 208. When moisture and oxygen from the external environment pass through the pinholes 210 and permeate or diffuse into the film layer under the insulating layer 208, moisture and oxygen undergo an oxidation/diffusion in the transparent metal oxide layer 206, thereby forming a diffused oxide 220 as shown in FIGS. 7 and 8.

In particular, since the transparent metal oxide layer 206 is an oxide material, when moisture and oxygen diffuse or permeate into the transparent metal oxide layer 206, the oxidation effect generated by moisture and oxygen in the transparent metal oxide layer 206 is limited or slow. In other words, moisture and oxygen are resisted by the transparent metal oxide layer 206 and can not diffuse to the metal electrode. Since the transparent metal electrode 204 and the transparent conductive layer 202 located under the transparent metal oxide layer 206 are not oxidized or corroded by moisture and oxygen, the transparent metal electrode 204 and the transparent conductive layer 202 can obtain their original electric properties.

Similarly, the conductive film structure 20 can be disposed on the substrate 100 or the electronic device 200.

The substrate 100 can be a rigid substrate (e.g. a glass substrate or a silicon substrate) or a flexible substrate (e.g. a plastic substrate or a metal substrate). Since the conductive film structure 20 in the exemplary embodiment is a transparent conductive film, the conductive film structure 20 disposed on the substrate 100 can be a simple transparent conductive wire structure, a transparent electrode structure, or a transparent conductive layer structure.

According to another exemplary embodiment, the conductive film structure 20 is disposed on the electronic device 200 to constitute the electronic apparatus. The electronic device 200 includes a display device, a solar cell device, an LED device, a flexible circuit board device, or a field effect transistor device. In other words, the conductive film structure 20 disposed on the electronic device 200 is applied as a part of the electronic apparatus. When disposed on the solar cell device, the conductive film structure 20 can be utilized as an electrode in the solar cell device. When disposed on the LED device, the conductive film structure 20 can be adopted as an electrode layer in the LED device. Being transparent or light transmissive, the conductive film structure 20 in the exemplary embodiment can be applied in devices that need light transmission. For example, the conductive film structure 20 in the exemplary embodiment can be adopted as the transparent electrode layer in the solar cell device or the transparent electrode layer in the LED device.

In summary, in the conductive film structure of the disclosure, the metal oxide layer is formed between the insulating layer and the metal electrode (or the transparent metal electrode), and the pinholes in the insulating layer contact the metal oxide layer. Accordingly, moisture and oxygen from the external environment can diffuse and permeate into the metal oxide layer through the pinholes. Particularly, the metal oxide layer prevents moisture and oxygen from permeating or diffusing downward to the metal electrode (or the transparent metal electrode), and therefore the metal electrode (or the transparent metal electrode) is not oxidized or corroded by moisture and oxygen. Thus, the metal electrode (or the transparent metal electrode) can obtain its original electric property so that the device performance of the electronic apparatus adopting this conductive film is not affected.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A conductive film structure capable of resisting moisture and oxygen, comprising:
a metal electrode;
a metal oxide layer disposed on the metal electrode, wherein a material of the metal oxide layer is an oxide of the metal electrode; and
an insulating layer covering the metal oxide layer.

2. The conductive film structure capable of resisting moisture and oxygen as claimed in claim 1, wherein the insulating layer comprises at least one pinhole passing through the insulating layer such that one end of the pinhole contacts the metal oxide layer.

3. The conductive film structure capable of resisting moisture and oxygen as claimed in claim 1, wherein the metal electrode comprises a metal or a composite metal.

4. The conductive film structure capable of resisting moisture and oxygen as claimed in claim 3, wherein the metal comprises aluminum (Al), copper (Cu), silver (Ag), platinum (Pt), or gold (Au), and the composite metal comprises silver/copper (Ag/Cu), aluminum/silver (Al/Ag), aluminum/platinum (Al/Pt), gold/copper (Au/Cu), platinum/gold (Pt/Au), or zinc/copper (Zn/Cu).

5. The conductive film structure capable of resisting moisture and oxygen as claimed in claim 4, wherein the metal oxide layer comprises aluminum oxide, copper oxide, silver oxide, platinum oxide, or gold oxide.

6. The conductive film structure capable of resisting moisture and oxygen as claimed in claim 5, wherein the metal oxide layer has a thickness ranging from 1 nanometer (nm) to 5 nm.

7. The conductive film structure capable of resisting moisture and oxygen as claimed in claim 1, wherein the insulating layer comprises silicon oxide, silicon nitride, titanium oxide, ethylene vinyl acetate (EVA), epoxy, polytetrafluoroethylene (PTFE), ethylene-tetrafluoroethylene (ETFE), or a combination thereof.

8. A conductive film structure capable of resisting moisture and oxygen, comprising:
a transparent conductive layer;
a transparent metal electrode disposed on the transparent conductive layer;
a transparent metal oxide layer disposed on the transparent metal electrode, wherein a material of the transparent metal oxide layer is an oxide of the transparent metal electrode; and
an insulating layer covering the transparent metal oxide layer.

9. The conductive film structure capable of resisting moisture and oxygen as claimed in claim 8, wherein the insulating layer comprises at least one pinhole passing through the insulating layer such that one end of the pinhole contacts the transparent metal oxide layer.

10. The conductive film structure capable of resisting moisture and oxygen as claimed in claim 8, wherein the transparent conductive layer comprises an inorganic conductive material or an organic conductive material.

11. The conductive film structure capable of resisting moisture and oxygen as claimed in claim 10, wherein the inorganic conductive material comprises indium tin oxide (ITO), fluorine-doped tin oxide (FTO), zinc oxide (ZnO), aluminum-doped zinc oxide (AZO), indium zinc tin oxide (IZTO) or silver nano-wires, and the organic conductive material comprises conjugated polymer, carbon nanotube, or graphene.

12. The conductive film structure capable of resisting moisture and oxygen as claimed in claim 8, wherein the transparent metal electrode has a thickness ranging from 5 nm to 10 nm.

13. The conductive film structure capable of resisting moisture and oxygen as claimed in claim 12, wherein the transparent metal electrode comprises a metal or a composite metal.

14. The conductive film structure capable of resisting moisture and oxygen as claimed in claim 13, wherein the metal comprises aluminum, copper, silver, platinum, or gold, and the composite metal comprises silver/copper, aluminum/silver, aluminum/platinum, gold/copper, platinum/gold, or zinc/copper.

15. The conductive film structure capable of resisting moisture and oxygen as claimed in claim 14, wherein the transparent metal oxide layer comprises aluminum oxide, copper oxide, silver oxide, platinum oxide, or gold oxide.

16. The conductive film structure capable of resisting moisture and oxygen as claimed in claim 8, wherein the transparent metal oxide layer has a thickness ranging from 1 nm to 5 nm.

17. The conductive film structure capable of resisting moisture and oxygen as claimed in claim 8, wherein the insulating layer comprises silicon oxide, silicon nitride, titanium oxide, ethylene vinyl acetate, epoxy, polytetrafluoroethylene (PTFE), ethylene-tetrafluoroethylene (ETFE), or a combination thereof.

18. An electronic apparatus, comprising:
an electronic device; and
a conductive film structure capable of resisting moisture and oxygen, disposed on a surface of the electronic device, wherein the conductive film structure capable of resisting moisture and oxygen is as claimed in claim 1.

19. The electronic device as claimed in claim 18, wherein the electronic device comprises a display device, a solar cell device, a light emitting diode device, a flexible circuit board device, or a field effect transistor device.

20. An electronic device, comprising:
an electronic apparatus; and
a conductive film structure capable of resisting moisture and oxygen, disposed on a surface of the electronic device, wherein the conductive film structure capable of resisting moisture and oxygen is as claimed in claim 8.

21. The electronic device as claimed in claim 20, wherein the electronic device comprises a display device, a solar cell device, a light emitting diode device, a flexible circuit board device, or a field effect transistor device.
